(19) United States
(12) Patent Application Publication
(10) Pub. No.: US 2010/0059654 A1
(43) Pub. Date: Mar. 11, 2010

(54) Protective holder for hall-based speed sensor

(76) Inventors: Antonio Gonzalez, El Paso, TX (US); Tania C. Vazquez, Cd. Juarez, Chihuahua (MX); Salvador Sandoval, El Paso, TX (US); Cruz Gerardo Gonzalez, Cd. Juarez, Chihuahua (MX); Oscar Gonzalez, El Paso, TX (US)

Correspondence Address: Delphi Technologies, Inc., M/C 480-410-202, PO BOX 5052, Troy, MI, 48007, US

(21) Appl. No.: 12/231,825

(22) Filed: Sep. 5, 2008

(51) Int. Cl. F16M 11/00; A47G 29/00; G01R 33/07

(52) U.S. Cl. 248/682; 248/694; 324/117 H

(57) ABSTRACT

A sensor assembly includes a lead frame holding a Hall sensor. The lead frame is sandwiched between top and bottom unitarily molded plastic holder halves to protect the lead frame during subsequent overmolding.

### FIELD OF THE INVENTION

The present invention relates generally to protective holders for speed sensors.

### BACKGROUND OF THE INVENTION

Speed sensors are used in vehicles for a wide variety of applications, e.g., to sense the linear or rotational speed of various components so as to control other components accordingly. For example, anti-lock brake systems may require speed input to control properly.

Hall effect sensors may be used in non-contact sensor types to sense the passage of a magnet on the component whose speed is sought to be measured. As understood herein, when the lead frame on which a Hall sensor is mounted is overmolded with plastic to form a sensor body, relatively costly structure may be required to protect the Hall sensor, and/or the Hall sensor might be exposed to the environment. Furthermore, part failure can result from certain manufacturing steps, leading to increased warranty costs.

### SUMMARY OF THE INVENTION

A sensor assembly includes a lead frame holding a sensor. The lead frame is sandwiched between top and bottom unitarily molded plastic holder halves.

In some embodiments the bottom holder half is a generally elongated plastic structure on which the lead frame is disposed. A central post can be formed on the bottom holder half. The post can extend through an opening of the lead frame for close reception of the post in a complementarily-shaped opening of the top holder half.

If desired, the bottom holder half can include a partially enclosed end cavity in which the sensor is disposed when the lead frame is mounted on the bottom holder half. A disk-shaped solid flange can be formed at an end of the bottom holder half to protect during overmolding objects that are disposed in the cavity.

In some implementations, plural solid, generally paralellepiped-shaped ribs are formed on the bottom holder half to engage respective openings of the lead frame to securely hold the lead frame onto the bottom holder half during overmolding. The ribs may be formed on the same surface of the bottom holder half as is the post. Also, solid guides can be formed on a side surface of the bottom holder half that is orthogonal to the surface on which the post is formed, so that the guides maintain the assembly in place in a mold during subsequent overmolding.

Hall lead support protrusions may also be formed on the surface on which the post is formed adjacent the end cavity to support components on the lead frame. Opposite the end cavity, the bottom holder half may be formed with terminal supports for receiving terminals associated with the lead frame. Wires that are connected to the terminals can be received in wire channels of the top holder half.

Turning to the top holder half, in some embodiments transverse semi-cylindrical cradles can be formed on the top holder half to accommodate and protect the sensor. Also, one or more pair of solid, transversely-projecting position stops can protrude transversely away from the top holder half to maintain the position of the holder in a mold. The sensor may be a Hall effect sensor.

In another aspect, a holder for a sensor lead frame includes a bottom holder portion defined by a generally elongated plastic body against which the lead frame is disposed. A central post is formed on the bottom holder portion and is configured for extending through an opening of the lead frame.

In another aspect, a holder for a sensor lead frame includes a top holder portion including at least one pair of solid, transversely-projecting position stops protruding transversely away from a body of the top holder portion to maintain the position of the holder in a mold.

The details of the present invention, both as to its structure and operation, can best be understood in reference to the accompanying drawings, in which like reference numerals refer to like parts, and in which:

### BRIEF DESCRIPTION OF THE DRAWINGS

FIG. 1 is a block diagram of one non-limiting environment in which the present sensor may be used;

FIG. 2 is an exploded perspective view of an example embodiment; and

FIG. 3 is an isometric view of the embodiment shown in FIG. 2 in an assembled configuration.

### DETAILED DESCRIPTION OF THE PREFERRED EMBODIMENT

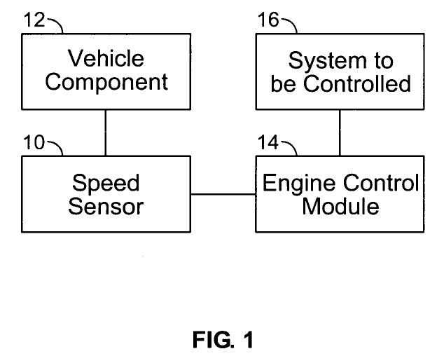

Referring initially to FIG. 1, a speed sensor 10 in accordance with present principles may be used to measure a linear or rotational speed of a vehicle component 12 such as a turbine shaft or drive shaft or other component. The speed sensor 10 can send speed signals to a controller 14 such as an engine control module (ECM) to control a system of component 16 such as a fuel injection system, anti-lock brake system, or other system in accordance with principles known in the art.

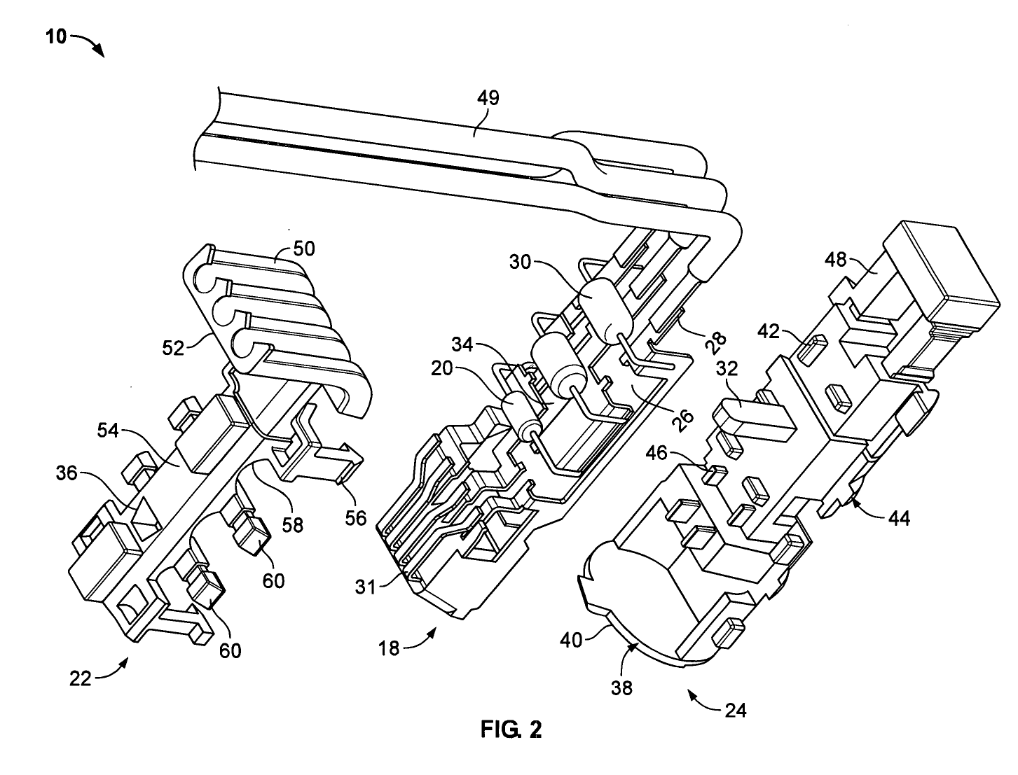

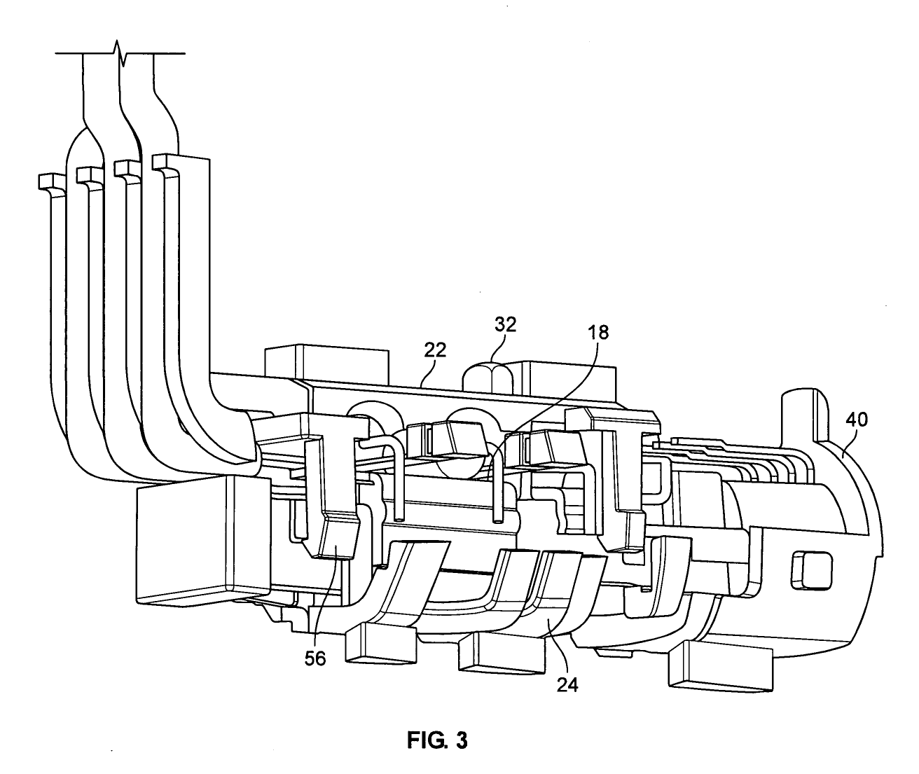

FIGS. 2 and 3 show an embodiment of the sensor 10. The sensor 10 includes a lead frame 18 holding a sensor 20 such as a Hall effect sensor. The lead frame is held sandwiched between top and bottom unitarily molded plastic holder halves 22, 24 in accordance with disclosure below.

As shown, the lead frame 18 may be a flat, parallelepiped-shaped unitary plastic frame with various openings 26 that mate with holder structure described further below. One or more elongated metal electrical terminals 28 are mounted on the lead frame 18 and extend away therefrom, it being understood that the terminals connect to external structure to establish communication between the Hall sensor 20 and, e.g., the ECM 14 shown in FIG. 1. Part of the sensor circuitry may include one or more resistors 30 that are also mounted on the lead frame 18. Circuit traces 31 may also be electrically connected to the above-discussed sensor components and may be juxtaposed with the lead frame 18 as shown.

As also shown, the bottom holder half 24 is a generally elongated plastic structure on which the lead frame 18 may be securely disposed. A central post 34 is provided on the bottom holder half 24, the post 34 may be non-round in cross-section, e.g., may be trapezoidal. The post may extend through an opening 34 of the lead frame 18 for close reception of the post 32 in a complementarily-shaped opening 36 of the top holder half 22.

As shown in FIG. 2, at the left end (looking down on FIG. 2) the bottom holder half 24 includes a partially enclosed end cavity 38 in which the Hall sensor 20 is disposed when the lead frame 18 is mounted on the bottom holder half 24. A disk-shaped solid flange 40 is formed at the left end of the bottom holder half 24 to protect during overmolding objects, e.g., the Hall sensor 20, that are disposed in the cavity 38.

Additionally, plural (e.g., seven) solid, relatively small, generally paralellepiped-shaped ribs 42 can be formed on the bottom holder half 24 to engage respective openings 26 of the lead frame 18 to securely hold the lead frame 18 onto the bottom holder half 24 during overmolding. As shown, plural of the ribs 42 are formed on the same surface of the bottom holder half 24 as is the post 32.

Additionally, plural solid, relatively small, generally paralellepiped-shaped guides 44 may be formed on side surfaces of the bottom holder half 24, i.e., on one or more surfaces that are orthogonal to the surface on which the post 32 is formed and on which the lead frame 18 is mounted. These guides 44 aid in maintaining the holder assembly in place in a mold during subsequent overmolding.

Still further, relatively small, generally paralellepiped-shaped Hall lead support protrusions 46 may be formed on the surface on which the post 32 is formed. The protrusions 46 may be formed adjacent the end cavity 38 as shown to support the circuit traces 31 of the lead frame 18 by, e.g., being received in openings 26 of the lead frame 18 near the traces 31.

Opposite the end cavity 38, the bottom holder half 24 may be formed with a terminal support 48 for supporting the terminals 28. The wires 49 that are connected to the terminals 28 may be received in wire channels 50 of the top holder half 22. The wire channels 50 as shown are formed in a portion 52 of the top holder half 22 that curves in a generally orthogonal orientation to a generally flat, parallelepiped-shaped cover portion 54 of the top holder half 22. Resilient downwardly-depending snaps 56 on the cover portion 54 may snappingly engage structure, e.g., the guides 44, on the bottom holder half 24 to further hold (along with the post 32/opening 36) the top holder half 22 on the bottom holder half 24 with the lead frame 18 sandwiched therebetween.

Transverse semi-cylindrical cradles 58 may be formed on the cover portion 54 to accommodate and protect one or more of the Hall sensor 20 and resistors 30 on the lead frame 18. Two pair of solid, transversely-projecting position stops 60 can protrude transversely away form the cover portion 54 as shown to maintain the position of the holder in a mold after the top holder half 22 and bottom holder half 24 have been snapped together with the lead frame 18 therebetween, to overmold additional sensor structure onto the holder assembly.

While the particular PROTECTIVE HOLDER FOR HALL-BASED SPEED SENSOR is herein shown and described in detail, it is to be understood that the subject matter which is encompassed by the present invention is limited only by the claims. For example, with the holder halves 22, 24 described above are made separately from each other, they may be made together as a single piece by overmolding them onto the lead frame.

What is claimed is:

1. A sensor assembly, comprising;
a lead frame holding a sensor;
the lead frame being sandwiched between top and bottom unitarily molded plastic holder halves.

2. The sensor of claim 1, wherein the bottom holder half is a generally elongated plastic structure on which the lead frame is disposed, a central post being formed on the bottom holder half, the post extending through an opening of the lead frame for close reception of the post in a complementarily-shaped opening of the top holder half.

3. The sensor of claim 2, wherein the bottom holder half includes a partially enclosed end cavity in which the sensor is disposed when the lead frame is mounted on the bottom holder half, a disk-shaped solid flange being formed at an end of the bottom holder half to protect during overmolding objects that are disposed in the cavity.

4. The sensor of claim 2, wherein plural solid, generally paralellepiped-shaped ribs are formed on the bottom holder half to engage respective openings of the lead frame to securely hold the lead frame onto the bottom holder half during overmolding, plural of the ribs being formed on the same surface of the bottom holder half as is the post.

5. The sensor of claim 2, wherein plural solid guides are formed on at least one side surface of the bottom holder half that is orthogonal to the surface on which the post is formed, the guides maintaining the assembly in place in a mold during subsequent overmolding.

6. The sensor of claim 3, wherein Hall lead support protrusions are formed on the surface on which the post is formed and adjacent the end cavity to support components on the lead frame.

7. The sensor of claim 3, wherein opposite the end cavity the bottom holder half is formed with terminal supports for receiving terminals associated with the lead frame.

8. The sensor of claim 7, wherein wires that are connected to the terminals are received in wire channels of the top holder half.

9. The sensor of claim 1, comprising transverse semi-cylindrical cradles formed on the top holder half to accommodate and protect at least the sensor.

10. The sensor of claim 1, comprising at least one pair of solid, transversely-projecting position stops protruding transversely away from the top holder half to maintain the position of the holder in a mold.

11. The assembly of claim 1, wherein the sensor is a Hall effect sensor.

12. A holder for a sensor lead frame, comprising:
a bottom holder portion defined by a generally elongated plastic body against which the lead frame is disposed, a central post being formed on the bottom holder portion, the post configured for extending through an opening of the lead frame.

13. The holder of claim 12, wherein the bottom holder portion includes a partially enclosed end cavity in which the sensor is disposed when the lead frame is mounted on the bottom holder portion, a disk-shaped solid flange being formed at an end of the bottom holder portion to protect during overmolding objects that are disposed in the cavity.

14. The holder of claim 12, wherein plural solid, generally paralellepiped-shaped ribs are formed on the bottom holder portion to engage respective openings of the lead frame to securely hold the lead frame onto the bottom holder portion, plural of the ribs being formed on the same surface of the bottom holder portion as is the post.

15. The holder of claim 12, wherein plural solid guides are formed on at least one side surface of the bottom holder portion that is orthogonal to the surface on which the post is formed, the guides maintaining the portion in place in a mold during subsequent overmolding.

16. The holder of claim 12, comprising a top holder portion, the lead frame being sandwiched between top and bottom holder portions, wherein wires that are connected to lead frame terminals are received in wire channels of the top holder portion.

17. The holder of claim 16, wherein the post is closely received in a complementarily-shaped opening of the top holder portion.

18. The holder of claim 16, comprising transverse semi-cylindrical cradles formed on the top holder portion to accommodate and protect at least the sensor.

19. A holder for a sensor lead frame, comprising:
a top holder portion including at least one pair of solid, transversely-projecting position stops protruding transversely away from a body of the top holder portion to maintain the position of the holder in a mold.

20. The holder of claim 19, comprising transverse semi-cylindrical cradles formed on the top holder portion to accommodate and protect at least the sensor.
